(19) United States
(12) Patent Application Publication
(10) Pub. No.: US 2014/0118919 A1
(43) Pub. Date: May 1, 2014

(54) MOUNTING APPARATUS FOR EXPANSION CARD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: WEI-DONG CONG, Shenzhen (CN); LEI LIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/689,677

(22) Filed: Nov. 29, 2012

(30) Foreign Application Priority Data
Oct. 31, 2012 (CN) 2012104263454

(51) Int. Cl. H05K 7/14; G06F 1/16

(52) U.S. Cl. CPC H05K 7/1461; G06F 1/16
USPC 361/679.32; 361/737

(57) ABSTRACT

An apparatus for mounting an expansion card module to a motherboard having a number of sockets includes a supporting frame and a fixing bracket slidably mounted to the supporting frame and fixed to an end of the expansion card module. The expansion card module can be inserted into any one of the card slots, with the fixing bracket able to slide along the supporting frame, to any desired position, before fixing the expansion card module in place.

### BACKGROUND

1. Technical Field

The present disclosure relates to an apparatus for mounting peripheral component interconnect (PCI) cards.

2. Description of Related Art

A number of expansion cards can be in a computer and engaged in the card slots of the motherboard of the computer to enhance functions of the computer. In mounting the expansion cards, the expansion cards are fixed to a fixing bracket at an end of the computer with a plurality of screws. However, the expansion cards can only be fixed in one particular position, making it very inflexible in the mounting of the expansion card.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIGS. 1 and 2 are exploded views of an embodiment of a mounting apparatus, an expansion card, a riser card, and a chassis, but shown from different perspectives, wherein the mounting apparatus includes a supporting frame and a fixing bracket.

FIG. 3 is an enlarged view of the fixing bracket of FIG. 1.

FIGS. 4 and 5 are assembled views of the items of FIG. 1, showing the expansion card mounted in different positions.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

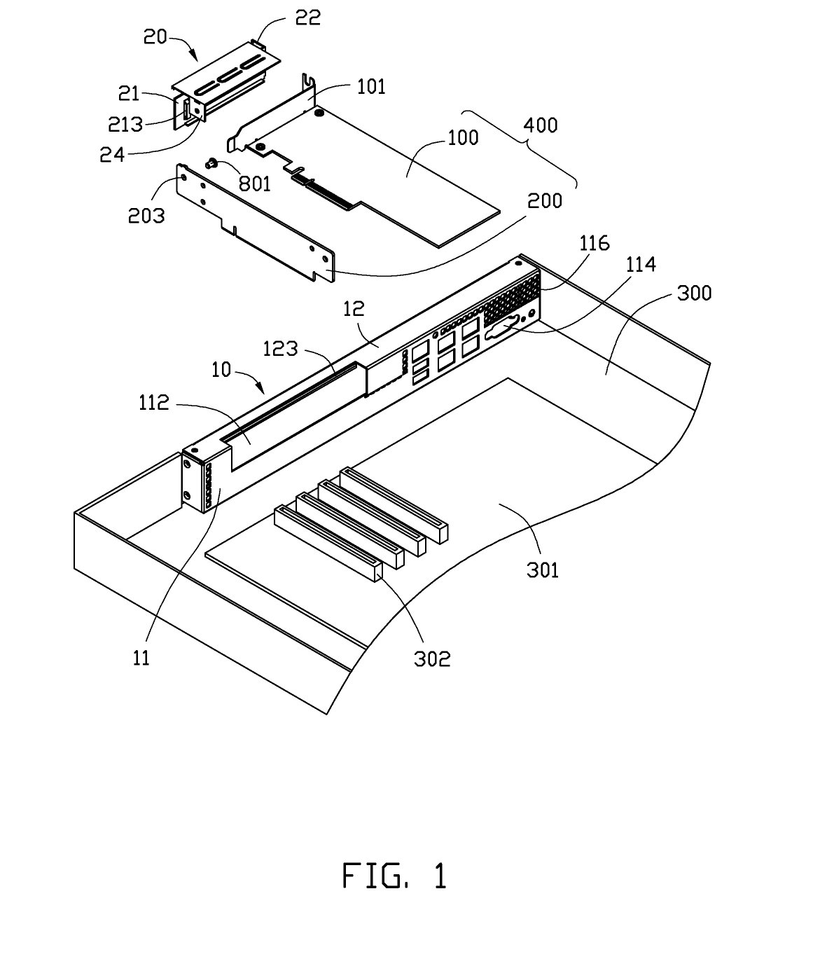

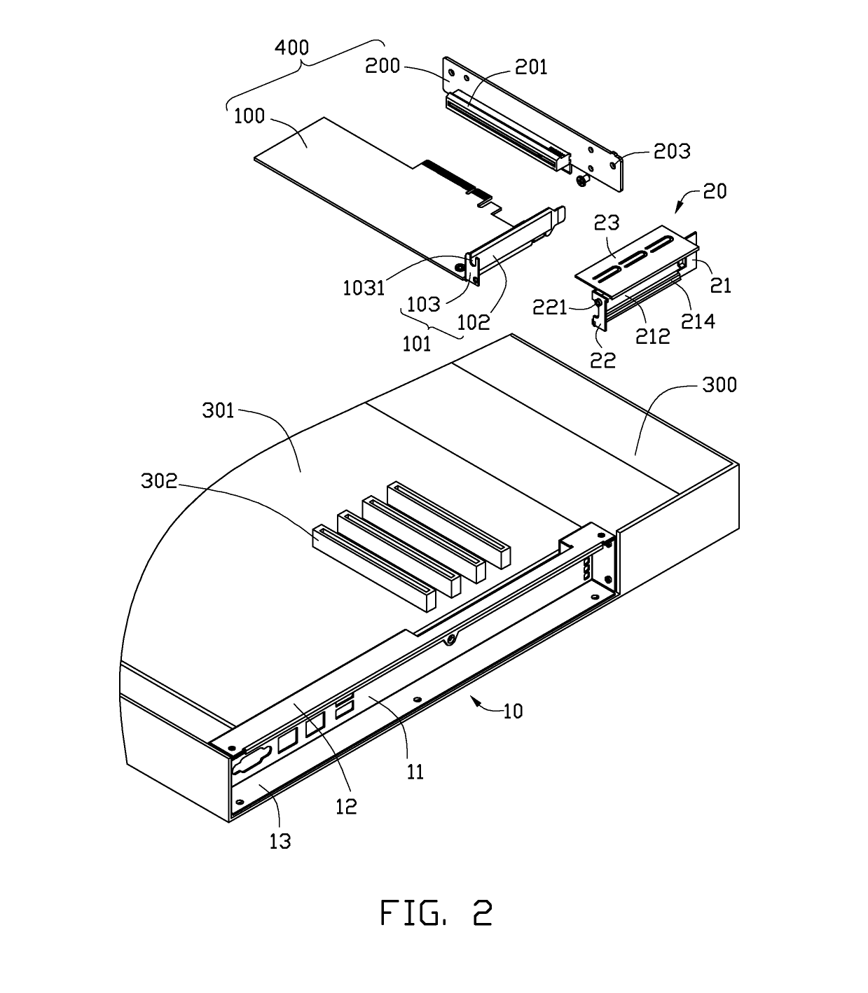

Referring to FIGS. 1 and 2, an exemplary embodiment of a mounting apparatus mounts an expansion card module 400 to a chassis 300 of a computer. In the embodiment, the expansion card module 400 includes an expansion card 100 and a riser card 200. The mounting apparatus includes a supporting frame 10 and a fixing bracket 20.

A motherboard 301 is mounted in the chassis 300, and includes a plurality of parallel sockets 302.

The expansion card 100 includes an L-shaped mounting piece 101 at end of the expansion card 100. The mounting piece 101 includes a mounting portion 102 and a bent portion 103 perpendicularly extending from an end of the mounting portion 102. A locating notch 1031 is defined in a top side of the bent portion 103.

The riser card 200 includes a socket 201 and defines an adjacent fixing hole 203 in a rear end of the riser card 200.

The supporting frame 10 is fixed to a rear end of the chassis 300. The supporting frame 10 includes a rectangular sidewall 11 facing the motherboard 301, a top wall 12 perpendicularly extending rearward from a top side of the sidewall 11, and a bottom wall 13 perpendicularly extending rearward from a bottom side of the sidewall 12. The sidewall 11 defines a plurality of connector holes 114 and a plurality of vents 116 adjacent to an end of the sidewall 11. A mounting opening 112 is defined in the sidewall 11 through the top wall 12 and aligned with the sockets 302 of the motherboard 301. A guide rail 123 is connected to the top wall 12 and extends the length of a side of the mounting opening 112.

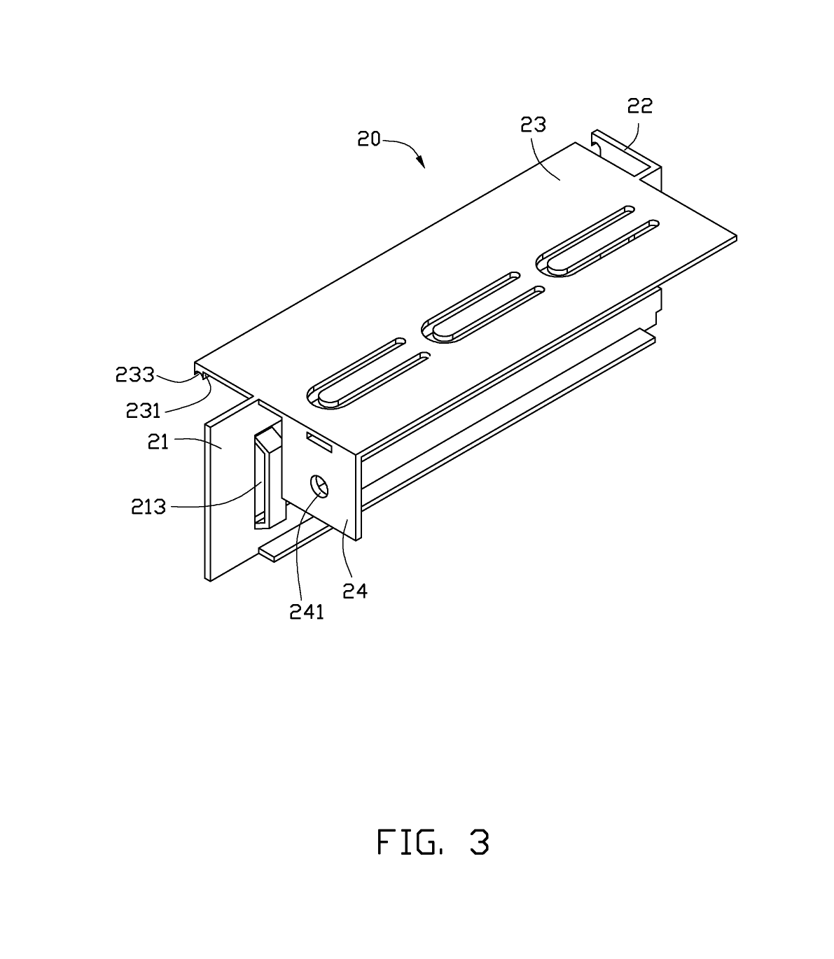

Referring to FIG. 3, the fixing bracket 20 includes a shielding plate 23, a blocking plate 21 perpendicularly extending down from a middle of the shielding plate 23, a substantially L-shaped first locating plate 22 perpendicularly extending rearwards from a first end of the blocking plate 21, and a second locating plate 24 perpendicularly extending down from a second end of the shielding plate 23. The second locating plate 24 is perpendicular to, and in front of, the blocking plate 21. A lengthwise alignment opening 212 is defined in the blocking plate 21. The blocking plate 21 includes a hook 214, extending rearward from a side bounding the bottom side of the alignment opening 212. A bridge-shaped tab 213 protrudes from a front side of the blocking plate 21, adjacent to an end of the alignment opening 212 and near the second locating plate 24. A bar 231 protrudes from a bottom of the shielding plate 23 and extends along the underside of the shielding plate 23. The bar 23 longitudinally defines a slide slot 233. A standoff 221 protrudes from an outside of the first locating plate 22. The second locating plate 24 defines a locating hole 241.

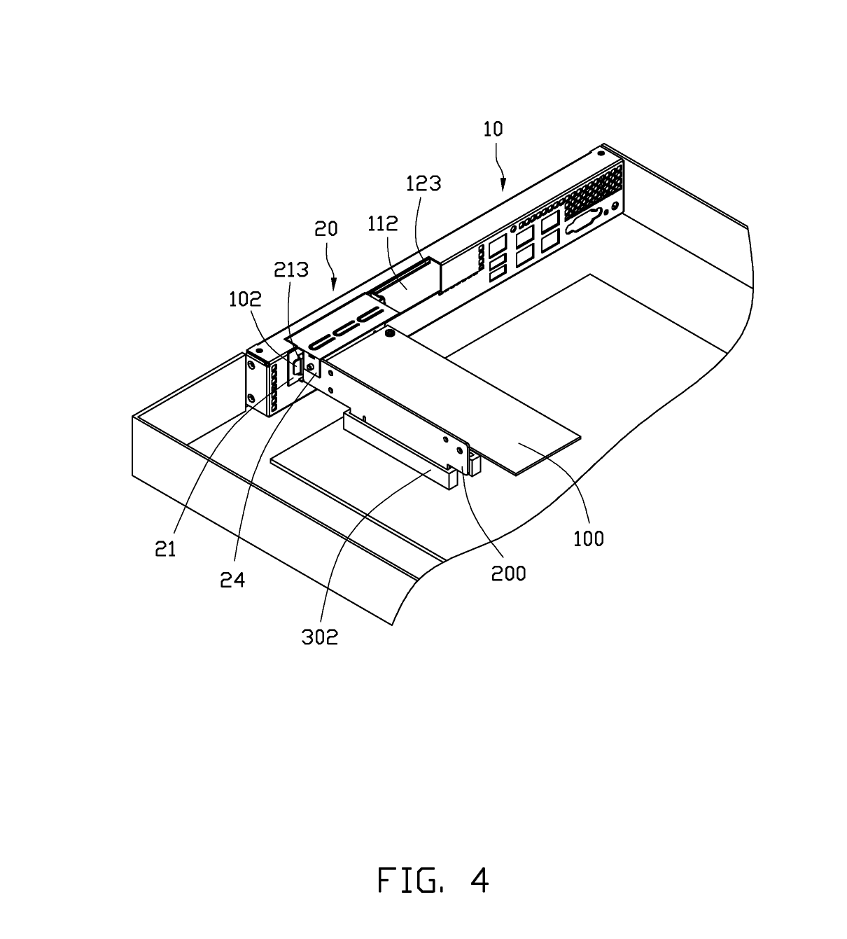

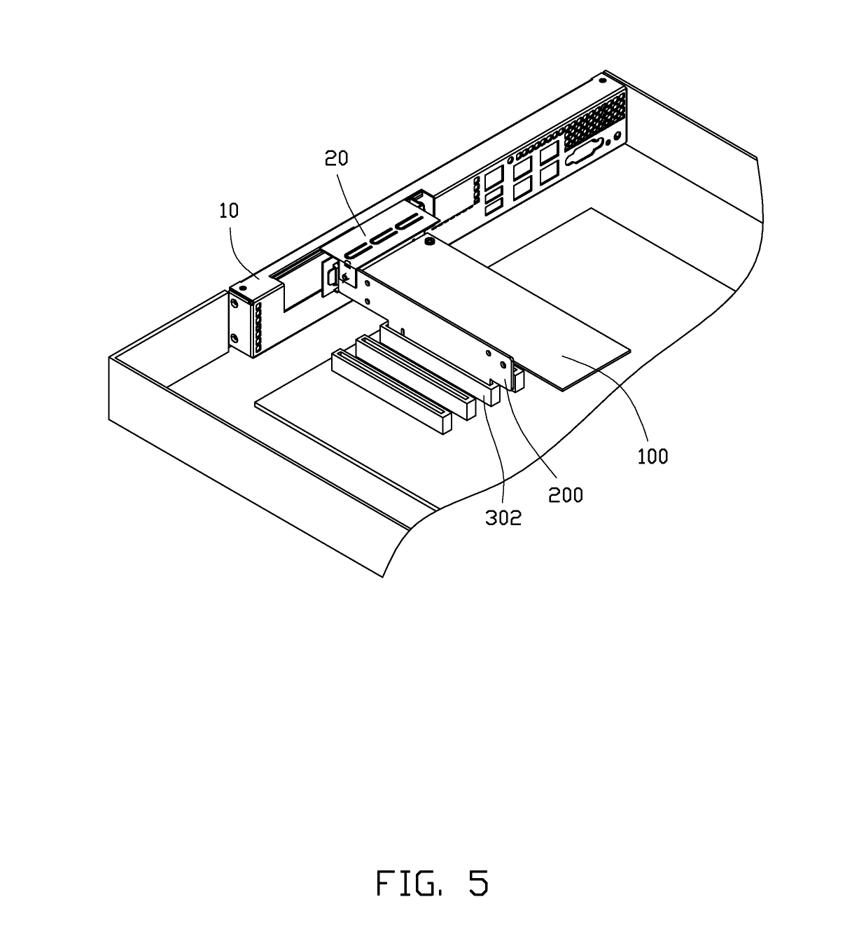

Referring to FIGS. 4 and 5, in assembly, the riser card 200 abuts the outside of the second locating plate 24, with the fixing hole 203 of the riser card 200 aligned with the locating hole 241 of the second locating plate 24. A screw 801 extends through the locating hole 241, for fastening in the fixing hole 203, to fix the riser card 200 to the fixing bracket 20.

The expansion card 100 is inserted into the socket 201 of the riser card 200. The mounting portion 102 abuts the front side of the blocking plate 21 and is aligned with the alignment opening 212 of the blocking plate 21. An end of the mounting portion 102 furthest away from the bent portion 103 is engaged between the tab 213 and the blocking plate 21. The bent portion 103 of the mounting piece 101 abuts the first locating plate 22, with the standoff 221 engaging in the locating notch 1031 of the bent portion 103, to fix the expansion card 100 to the fixing bracket 20.

The expansion card module 400 is mounted in the chassis 300, with the riser card 200 inserted in one of the sockets 302. The fixing bracket 20 is received in the mounting opening 112, with a sidewall bounding a bottom side of the mounting opening 112, and slidably engaged with the hook 214 of the fixing bracket 20 and the guide rail 123 being slidably engaged in the slide slot 233 of the fixing bracket 20.

Since the fixing bracket 20 can slide along the mounting opening 112 of the supporting frame 10, the position of the fixing bracket 20 is adjustable to the same extent as to enable the riser card 200 to be inserted into any one selected socket 302 of the motherboard 301.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus to mount an expansion card module to a chassis, the mounting apparatus comprising:
a supporting frame fixed to an end of the chassis; and
a fixing bracket fixed to an end of the expansion card module, and slidably mounted to the supporting frame to mount the expansion card at different positions in the chassis.

2. The mounting apparatus of claim 1, wherein the supporting frame defines a lengthwise mounting opening, and comprises a guide rail extending along a top sidewall bounding a first lengthwise side of the mounting opening, the fixing bracket comprises a shielding plate and a blocking plate perpendicularly extending down from a middle of the shielding plate, the shielding plate defines a slide slot, the guide rail is slidably engaged in the slide slot of the shield plate, a hook extends from the blocking plate and slidably engages with a sidewall bounding a second lengthwise side of the mounting opening of the supporting frame.

3. The mounting apparatus of claim 2, wherein the shielding plate comprises a bar extending along a side of the shielding plate, the slide slot is defined in the bar and extends along a lengthwise direction of the bar.

4. A computer, comprising:
a chassis;
a motherboard mounted in the chassis and comprising two sockets;
a supporting frame fixed to the chassis;
a fixing bracket mounted to the supporting frame; and
an expansion card module fixed to the fixing bracket and configured to be inserted into any one of the two sockets;
wherein the fixing bracket is slidable relative to the supporting frame between a first position in response to the expansion card module being inserted into one of the two sockets of the motherboard, and a second position in response to the expansion card module being inserted into the other socket of the motherboard.

5. The computer of claim 4, wherein the supporting frame defines a mounting opening aligned with the sockets of the motherboard and slidably receiving the fixing bracket.

6. The computer of claim 5, wherein the supporting frame further comprises a guide rail extending along a sidewall bounding a top lengthwise side of the mounting opening, the fixing bracket comprises a shielding plate and a blocking plate perpendicularly extending downwards from a middle of the shielding plate, the shielding plate defines a slide slot, the guide rail is slidably engaged in the slide slot of the shield plate, a hook extends from the blocking plate and slidably engages with a sidewall bounding a bottom lengthwise side mounting opening of the supporting frame.

7. The computer of claim 6, wherein the expansion card module comprises a riser card inserted in one of the sockets of the motherboard and an expansion card engaged with and electrically connected to the riser card, the expansion card comprises an L-shaped mounting piece fixed to the fixing bracket.

8. The computer of claim 7, wherein the fixing bracket further comprises a first locating plate perpendicularly extending from a side of the blocking plate, the mounting piece of the expansion card comprises a mounting portion abutting the blocking plate of the fixing bracket, and a bent portion perpendicularly extending from an end of the mounting portion and abutting the first locating plate of the fixing bracket.

9. The computer of claim 8, wherein a bridge-shaped tab protrudes on a surface of the blocking plate, an end of the mounting portion of the mounting piece of the expansion card opposite to the bent portion is engaged between the bridge-shaped tab and the blocking plate.

10. The computer of claim 8, wherein the bent portion of the mounting piece of the expansion card defines a locating notch, a standoff protrudes on the first locating plate of the fixing bracket and engaged in the locating notch of mounting piece of the expansion card.

11. The computer of claim 8, wherein the fixing bracket further comprises a second locating plate extending downwards from the shielding plate, the riser card is fixed to the second locating plate.
